(19) United States
(12) Patent Application Publication
(10) Pub. No.: US 2009/0159936 A1
(43) Pub. Date: Jun. 25, 2009

(54) DEVICE WITH ASYMMETRIC SPACERS

(76) Inventors: Uday Shah, Portland, OR (US); Ibrahim S. Ban, Beaverton, OR (US); Willy Rachmady, Beaverton, OR (US)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 11/961,926

(22) Filed: Dec. 20, 2007

(51) Int. Cl. H01L 21/336; H01L 29/78

(52) U.S. Cl. 257/288; 438/286; 257/E29.255; 257/E21.409

(57) ABSTRACT

An asymmetrical spacer adjacent a gate is formed. This asymmetry is used to form offset regions in a device.

### BACKGROUND

### BACKGROUND OF THE INVENTION

Devices such as transistors have spacers adjacent to a gate electrode. The spacers may be used to mask a substrate while a region, such as a source or drain region, of the substrate is doped.

### BRIEF DESCRIPTION OF THE DRAWINGS

FIG. 1 is a cross sectional side view that illustrates a device having an asymmetric spacer.

FIG. 2 is a cross sectional side view that illustrates the asymmetry of the device of FIG. 1.

FIGS. 3 and 4 are cross sectional side views that illustrate how the device shown in FIG. 1 may be formed.

FIG. 5 is a cross sectional side view that illustrates a different example of a device with asymmetric spacers.

FIG. 6 is a cross sectional side view that illustrates yet another example of a device with asymmetric spacers.

FIGS. 7 through 11 are cross sectional side views that illustrate how the asymmetrical spacers may be used to form offset regions of the device.

FIG. 12 is a cross sectional side view that illustrates a generalized final device with asymmetrical spacers.

### DETAILED DESCRIPTION

Various embodiments of devices with asymmetric spacers are discussed in the following description. One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative example representations and are not necessarily drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

Various operations will be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order, in series or in parallel, than the described embodiment. Various additional operations may be performed and/or described operations may be omitted in additional embodiments.

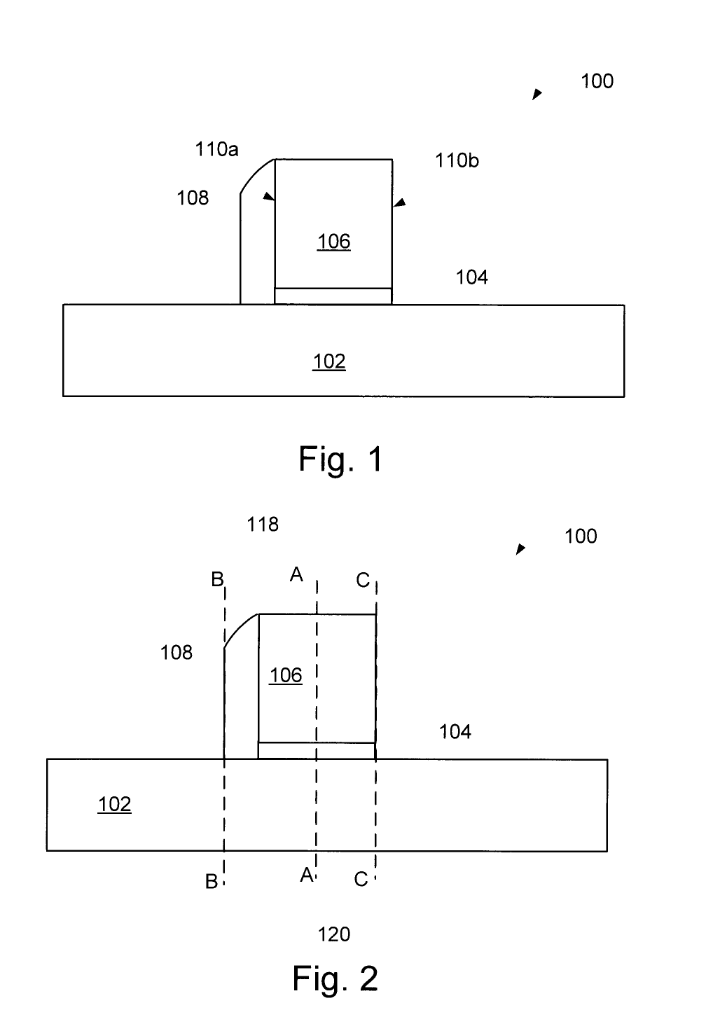

FIG. 1 is a cross sectional side view that illustrates a device 100 having an asymmetric spacer 108. In the illustrated example, there is a substrate 102. This substrate 102 may comprise any material that may serve as a foundation upon which a semiconductor device may be built. In one example, substrate 102 is a silicon containing substrate, although other materials may be used in other examples. The substrate 102 may be a bulk substrate, such as a wafer of single crystal silicon, a silicon-on-insulator (SOI) substrate, such as a layer of silicon on a layer of insulating material on another layer of silicon, or another type of substrate.

In the example, there is a gate dielectric layer 104 formed on the substrate 102 and a gate electrode 106 on the gate dielectric layer 104. In one embodiment, the gate electrode 106 comprises polysilicon and the gate dielectric layer 104 comprises silicon dioxide. In another embodiment, the gate electrode 106 comprises a metal material and the gate dielectric layer 104 comprises a high-k material such as a hafnium oxide or other high-k material. In yet other embodiments, the gate dielectric layer 104 and gate electrode 106 may comprise different materials suitable for use as a gate dielectric layer 104 and gate electrode 106. In various embodiments, the gate electrode 106 may be a gate electrode 106 for a planar transistor, a gate electrode 106 for a multi-gate transistor, or a gate electrode 106 for another type of transistor.

In the embodiment shown in FIG. 1, the device 100 includes a spacer 108 adjacent to one sidewall 110a of the gate electrode 106. The other sidewall 110b of the gate electrode 106 that is laterally opposite from the first sidewall 110a does not have a spacer adjacent to it. Thus, the device 100 of FIG. 1 has an asymmetrical spacer configuration. Note that while the device 100 is shown and described as having a gate dielectric layer 104 and gate electrode 106, in other embodiments, the device 100 may lack these features and yet still have asymmetric spacers.

FIG. 2 is a cross sectional side view that illustrates the asymmetry of the device 100 of FIG. 1. Spacers are frequently used to protect areas from being doped and thus position doped regions. Thus, FIG. 2 illustrates how doped regions may be offset. Dashed line A-A shows the center line of the gate electrode 106. Dashed line B-B shows the outer boundary of the spacer 108. Dashed line C-C shows the outer boundary of the gate electrode 106. The distance 118 between A-A and B-B is greater than the distance 120 between A-A and C-C. The difference in distance is equal to the difference in thickness of the spacer(s) 108 on either side of the gate electrode 106. Doped regions formed using the spacer 108/gate electrode 106 structure as a doping mask will be offset to the left. Doped regions to the right of the gate electrode 106 will be closer to the center line A-A of the gate electrode 106.than doped regions to the left of the gate electrode 106. This offset caused by the asymmetric spacer(s) 108 may enable the device 100 to have desired characteristics that could not be easily achieved with symmetrical spacers 108.

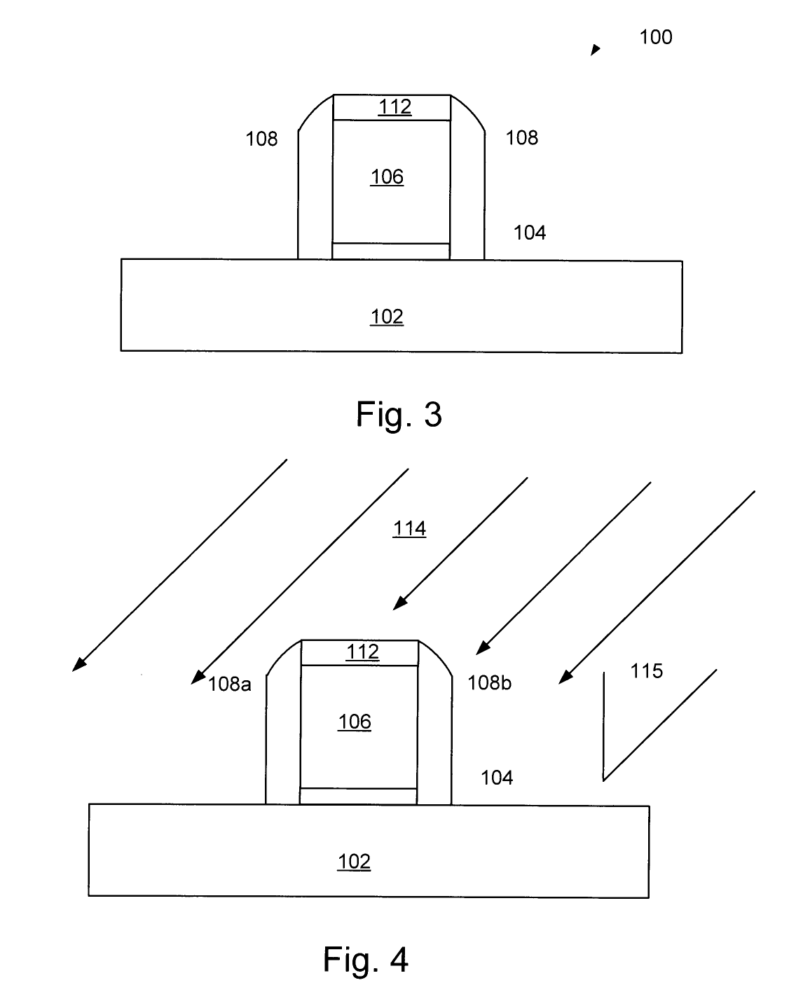

FIGS. 3 and 4 are cross sectional side views that illustrate how the device 100 shown in FIG. 1 may be formed, according to an embodiment. FIG. 3 illustrates the device 100 with spacers 108 on both sides of the gate electrode 106. The spacers 108 may comprise any suitable material, such as a nitride material, silicon dioxide, or another dielectric material. There may also be a hardmask layer 112 on the gate electrode 106.

FIG. 4 illustrates the device 100 being exposed to an angled microstructure-changing implant process. Ions 114 are implanted at an angle 115. The ions 114 may comprise arsenic, phosphorus, or other large or other materials. The angle 115 is over 45 degrees from vertical in some embodiments. The ions 114 may amorphize, damage, or otherwise change the microstructure of the right spacer 108b. As the ions 114 are implanted at an angle 115, the left spacer 108a is shielded from the ions 114 by the hardmask layer 112, gate electrode 106, gate dielectric layer 104, and even the other spacer 108b. Thus, the microstructure of the left spacer 108a is left relatively unchanged by the ions 114, while the right spacer 108b has its microstructure altered.

After altering the microstructure of one of the spacers 108, a selective etch is performed. An etchant is used that etches the spacer 108b with the changed microstructure much faster than the spacer 108a with the intact microstructure. For example, phosphoric acid may be used as an etchant where the spacers 108 comprise carbon-doped silicon nitride. In other embodiments, it may be possible to use an etchant that removes undamaged material at a faster rate than damaged material, and thus the spacer 108a that did not receive the ion implant would be removed. The result of this selective etch may be the removal of spacer 108b, as illustrated in FIG. 1.

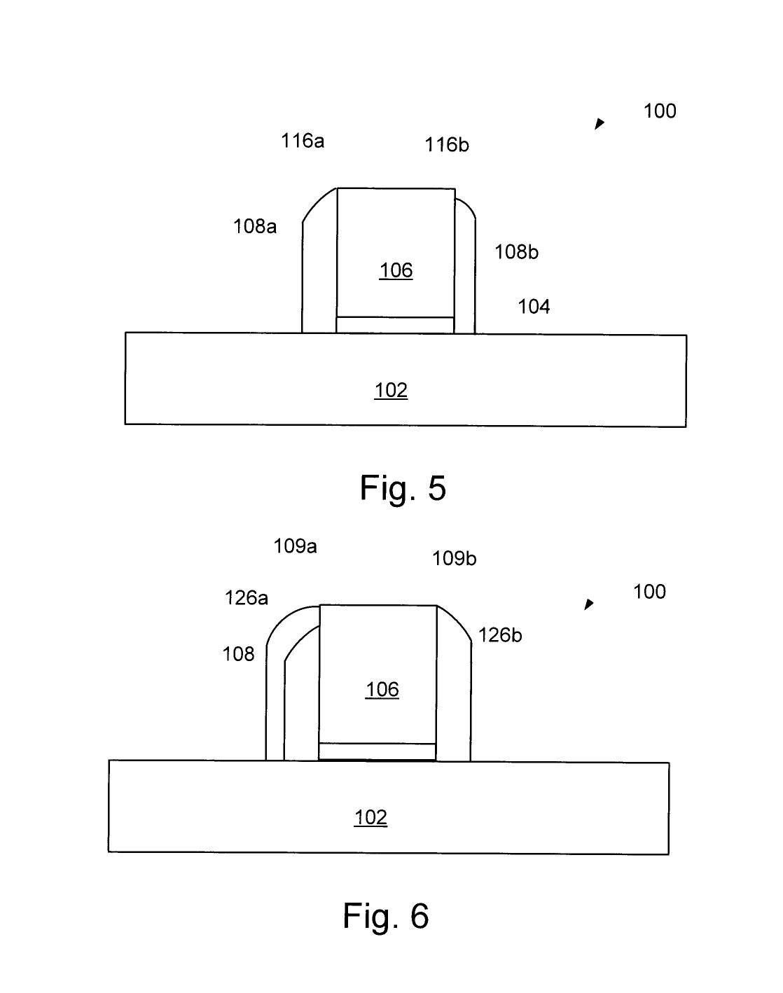

FIG. 5 is a cross sectional side view that illustrates a different example of a device 100 with asymmetric spacers 108. In this example, the spacer 108b on the right has not been completely removed as it was in FIG. 1. Rather, the spacer 108b on the right has been partially removed. As a result, it has a thickness 116b smaller than that of the thickness 116a of the spacer 108a on the left. This may be achieved by implanting ions 114 to a certain depth in spacer 108b and only changing the microstructure of the spacer 108b to that depth, leaving the rest of the spacer 108b with an unchanged microstructure. Such a spacer 108b would only be partially etched away by an etchant selective to material with the damaged microstructure. Alternatively, the spacer 108b may be exposed to the etchant for a limited period of time so that not all of the spacer 108b is removed. Other methods may also be used. As the thicknesses 116 of the spacers 108 are different, the distance between the outer boundary (the boundary further from the gate electrode 106) of the left spacer 108a and the center of the gate electrode 106 is larger than the distance between the outer boundary of the right spacer 108b and the center of the gate electrode 106. Thus, the spacers 108 are asymmetrical and can be used to form offset regions of the device 100.

FIG. 6 is a cross sectional side view that illustrates yet another example of a device 100 with asymmetric spacers 109. In this example, there are two spacer layers 108, 126a adjacent to the left side of the gate electrode 106 and only one layer of spacer material 126b adjacent to the right side of the gate electrode. This may be achieved by removing a spacer layer 108b (not shown in FIG. 6) from one side of the gate electrode 106, as illustrated and described with respect to FIGS. 1-4, and then adding another layer of spacer material 126 to both spacers 109. Other methods may also be used to create more spacer layers 108, 126a on one side of the gate electrode 106 than the other side. As the left spacer 109a, which includes spacer layers 108 and 126a, is thicker than the right spacer 109b, which only includes spacer layer 126b, the distance between the outer boundary (the boundary further from the gate electrode 106) of the left spacer 109a and the center of the gate electrode 106 is larger than the distance between the outer boundary of the right spacer 109b and the center of the gate electrode 106. Thus, the spacers 109 are asymmetrical and can be used to form offset regions of the device 100.

Different ways may be used to form the asymmetrical multi-layer spacers 109 as shown in FIG. 6. For example, the spacers 108 of FIG. 5, where one spacer layer 108b is thinned, may be used, with additional layer(s) of material added to make a final spacer 109b thinner on one side than the spacer 109a on the other side. Inner layers of material may be asymmetric, while outer layers may be thinned or removed from one side. More than two layers of spacer material may be used. Other suitable structures with asymmetrical spacers and methods to form the asymmetrical spacers are possible.

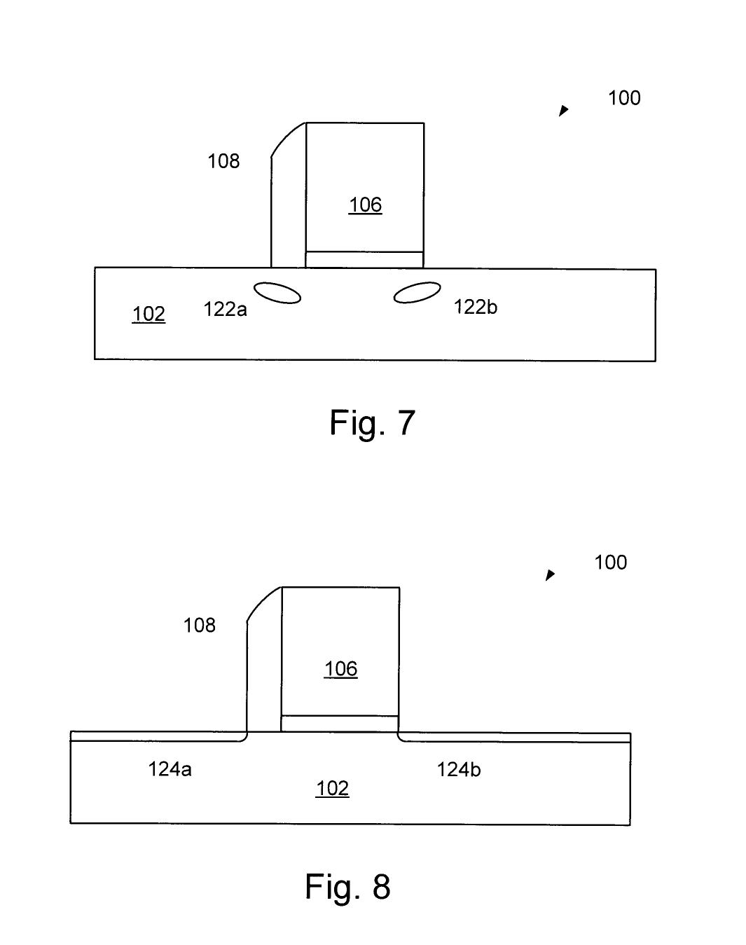

FIGS. 7 through 11 are cross sectional side views that illustrate how the asymmetrical spacers 108 may be used to form offset regions of the device 100. Regions that are offset from the gate 106 center may provide better performance or other desired characteristics than in a device 100 with regions that are symmetrical around the gate 106 center. Below are just a few examples of the regions that may be formed in an offset manner based on asymmetrical spacers 108 and may result in a better device 100. There are many other additional offset regions that are possible.

FIG. 7 is a cross sectional side view that illustrates offset halo regions 122 in a substrate 102 of a device. The halo regions 122 are formed by ion implantation and the location of the halo regions 122 are at least partially determined by the outer spacer 108 and gate 106 boundaries, which prevent the halo regions 122 from extending completely under the gate 106. As the outer spacer 108 boundary on the left is further from the gate 106 center than the right boundary of the gate 106, the left halo implant 122a is further from the center of the gate 106 than the right halo implant 122b; the halo implants 122 are offset to the left. While this is shown with a device 100 that has a spacer 108 on the left and not on the right, a similar offset of the halo regions 122 could be achieved by the thinned spacer 108 of FIG. 5, the multilayer spacers 109 with different thicknesses of FIG. 6, or other types of asymmetric spacers 108.

FIG. 8 is a cross sectional side view that illustrates offset tip junction regions 124 in a substrate 102 of a device 100. The tip junction regions 124 are formed by doping the substrate 102. The spacer 108 and gate 106 prevent the substrate 102 directly beneath from being doped as the tip junction regions 124 are formed. Thus, because the outer boundary of spacer 108 on the left is further from the gate 106 center than the right boundary of the gate 106, the left tip junction region 124a is further from the center of the gate 106 than the right tip junction region 124b; the tip junction regions 124 are offset to the left. While this is shown with a device 100 that has a spacer 108 on the left and not on the right, a similar offset of the tip junction regions 124 could be achieved by the thinned spacer 108 of FIG. 5, the multilayer spacers 109 with different thicknesses of FIG. 6, or other types of asymmetric spacers 108.

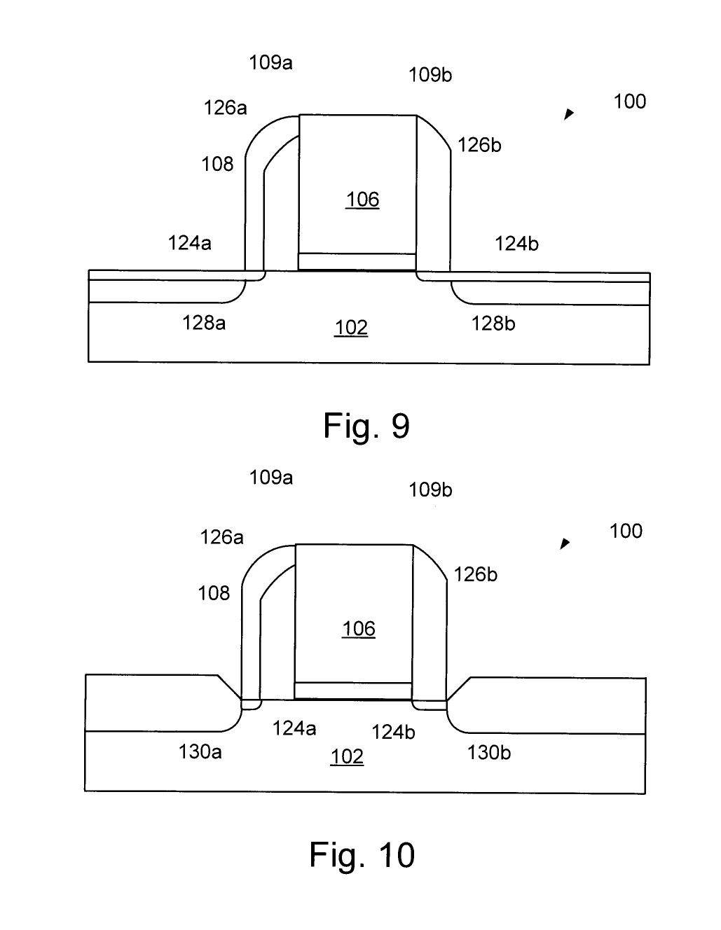

FIG. 9 is a cross sectional side view that illustrates offset source and drain regions 128 in a substrate 102 of a device 100. These source and drain regions 128 may be formed after the tip junction regions 124 described with respect to FIG. 8 in some embodiments. After the tip junction regions 124 are formed, another layer of spacer material 126 is added. This forms a multilayer spacer 109a on the left, with previously-present layer 108 in addition to new layer 126a. It also forms a spacer 109b on the right, with new layer 126b. As the thickness of layer 126a plus layer 108 is greater than that of layer 126b alone, the thickness of spacer 109a is greater than that of spacer 109b. The source and drain regions 128 may then be formed through ion implantation or another suitable method. The spacers 109 and gate 106 prevent the substrate 102 directly beneath from being doped as the source and drain regions 128 are formed. Thus, because the outer boundary of spacer 109a on the left is further from the gate 106 center than the outer boundary of spacer 109b on the right, the left source/drain region 128a is further from the center of the gate 106 than the right source/drain region 128b; the source and drain regions 128 are offset to the left. In an embodiment, it may be advantageous to have the source region closer to the gate 106 center, in which case source/drain region 128b on the right would be the source. In another embodiment, it may be advantageous to have the drain region closer to the gate 106 center, in which case source/drain region 128b on the right would be the drain. While this is shown with a device 100 that has a particular type of thicker spacer 109a on the left than the spacer 109b on the right, various other types of asymmetrical spacers 109 may be used to result in the same offset source/drain regions 128.

FIG. 10 is a cross sectional side view that illustrates offset epitaxial source and drain regions 130 in a substrate 102 of a device 100. The source and drain regions 130 of FIG. 10 are not implanted regions, but are formed by epitaxial growth. These source and drain regions 130 may be formed after the tip junction regions 124 described with respect to FIG. 8 in some embodiments. After the tip junction regions 124 are formed, another layer of spacer material 126 is added. This forms a multilayer spacer 109a on the left, with previously-present layer 108 in addition to new layer 126a. It also forms a spacer 109b on the right, with new layer 126b. As the thickness of layer 126a plus layer 108 is greater than that of layer 126b alone, the thickness of spacer 109a is greater than that of spacer 109b. Source and drain recesses may then be formed in the substrate 102. The spacers 109 and gate 106 prevent the substrate 102 directly beneath from being recessed. The source and drain 130 may then be formed by epitaxial growth in the recesses. Because the outer boundary of spacer 109a on the left is further from the gate 106 center than the outer boundary of spacer 109b on the right, the left source/drain region 130a is further from the center of the gate 106 than the right source/drain region 130b; the source and drain regions 130 are offset to the left. In an embodiment, it may be advantageous to have the source region closer to the gate 106 center, in which case source/drain region 130b on the right would be the source. In anther embodiment, it may be advantageous to have the drain region closer to the gate 106 center, in which case source/drain region 130b on the right would be the drain. While this is shown with a device 100 that has a particular type of thicker spacer 109a on the left than the spacer 109b on the right, various other types of asymmetrical spacers 109 may be used to result in the same offset source/drain regions 130.

FIG. 11 is a cross sectional side view that illustrates offset source and drain regions 128 in a substrate 102 of a device 100. The device 100 of FIG. 11 is similar to the device 100 of FIG. 9, except that tip junction regions 124 of the device of FIG. 11 are not offset. The tip junction regions 124 of the device 100 of FIG. 11 may be made as is known in the art, and be substantially symmetrical about the gate 106. Spacer layers 108 may then be formed and then thinned as described above. Alternatively, a thicker spacer 109a on one side of the gate 106 and a thinner spacer 109b on a second laterally opposite side of the gate 106 may be made with multiple spacer layers and removing one or more of the layers from the thinner spacer 109b side. The source and drain regions 128 may then be formed through ion implantation or another suitable method. The spacers 109 and gate 106 prevent the substrate 102 directly beneath from being doped as the source and drain regions 128 are formed. Thus, because the outer boundary of spacer 109a on the left is further from the gate 106 center than the outer boundary of spacer 109b on the right, the left source/drain region 128a is further from the center of the gate 106 than the right source/drain region 128b; the source and drain regions 128 are offset to the left even though the tip junction regions 124 are centered about the gate 106. In an embodiment, it may be advantageous to have the source region closer to the gate 106 center, in which case source/drain region 128b on the right would be the source. In another embodiment, it may be advantageous to have the drain region closer to the gate 106 center, in which case source/drain region 128b on the right would be the drain. While this is shown with a device 100 that has a particular type of thicker spacer 109a on the left than the spacer 109b on the right, various other types of asymmetrical spacers 109 may be used to result in the same offset source/drain regions 128.

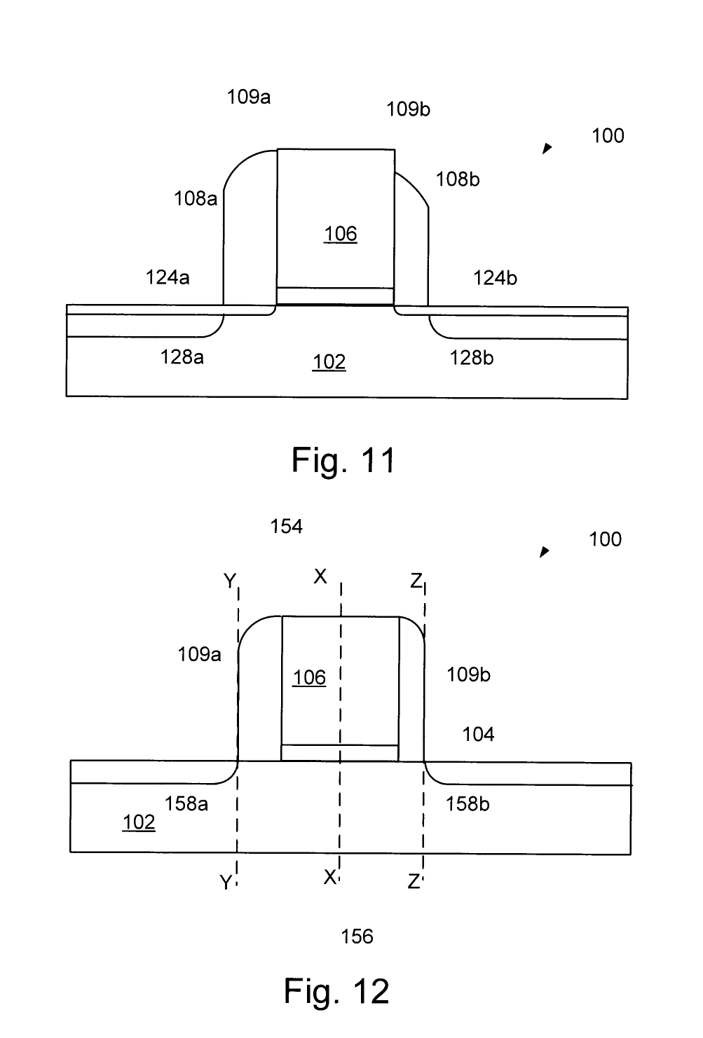

FIG. 12 is a cross sectional side view that illustrates a generalized final device 100 with asymmetrical spacers 109. The gate electrode 106 has outer sidewalls to the left and right. The device 100 has a thicker spacer 109a adjacent the left sidewall of the gate 106, and a thinner spacer 109b adjacent the right sidewall of the gate 106. These thinner 109b and thicker 109a spacers may be formed by a variety of methods and may be formed of a single layer or multiple layers. There is a greater distance 154 between the outer boundary Y-Y of the thicker spacer 109a and the center X-X of the gate 106 than the distance 156 between the outer boundary Z-Z of the thinner spacer 109b and the center X-X of the gate 106.

In an embodiment, the thicker spacer 109a of the final device 100 (“final device” meaning the device 100 after it is finished being made and as it exists in a product, such as a microprocessor, where it will be used) is at least 1 to 10 nm thicker than the thinner spacer 109b, in the case where the source and drain extension regions (tip) are offset. In another embodiment, the thicker spacer 109a of the final device 100 is at least 10 to 100 nm thicker than the thinner spacer 109b, in the case where the source and drain regions are offset. In another embodiment, the thicker spacer 109a is at least 10 nm thicker than the thinner spacer 109b. Other embodiments may have other thickness differences.

There may be regions 158 on either side of the gate 106, and these regions may be doped regions, epitaxially-grown regions, or other types of regions. These regions 158 may be offset by an amount about equal to the difference between distance 154 and distance 156, so that the region 158a on the side of the thicker spacer 109a is offset that much further away from the center of the gate 106 than the region 158b on the side of the thinner spacer 109b. Other embodiments may have other offset amounts.

In yet another embodiment, the final device 100 may have spacers 109 of equal thickness; asymmetric spacers 109 may have been used to form offset regions 158 but then the spacers 109 may have been made to be of roughly equal thickness again. Additional variations may be possible with yet other embodiments.

The foregoing description of the embodiments of the invention has been presented for the purposes of illustration and description. It is not intended to be exhaustive or to limit the invention to the precise forms disclosed. This description and the claims following include terms, such as left, right, top, bottom, over, under, upper, lower, first, second, etc. that are used for descriptive purposes only and are not to be construed as limiting. For example, terms designating relative vertical position refer to a situation where a device side (or active surface) of a substrate or integrated circuit is the “top” surface of that substrate; the substrate may actually be in any orientation so that a “top” side of a substrate may be lower than the “bottom” side in a standard terrestrial frame of reference and still fall within the meaning of the term “top.” The term “on” as used herein (including in the claims) does not indicate that a first layer “on” a second layer is directly on and in immediate contact with the second layer unless such is specifically stated; there may be a third layer or other structure between the first layer and the second layer on the first layer. The embodiments of a device or article described herein can be manufactured, used, or shipped in a number of positions and orientations. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

I claim:

1. A semiconductor device, comprising:
a gate electrode having a first sidewall and a second sidewall, the second sidewall being laterally opposite from the first sidewall;
a first spacer adjacent the first sidewall and having a first thickness; and
a second spacer adjacent the second sidewall of the gate electrode, the second spacer having a second thickness less than the first thickness.

2. The device of claim 1, wherein the first spacer has a first number of layers of material and the second spacer has a second number of layers of materials, the first number being larger than the second number.

3. The device of claim 1, further comprising:
a first region on a first side of a center line of the gate electrode, wherein the first spacer is also to the first side of the center line of the gate electrode;
a second region on a second side of the center line of the gate electrode opposite from the first side, wherein the second spacer is also to the second side of the center line of the gate electrode; and
wherein the second region is closer to the center line of the gate electrode than the first region.

4. The device of claim 3, wherein the first and second regions are tip junction regions.

5. The device of claim 3, wherein the first and second regions are source and drain regions.

6. The device of claim 3, wherein the first and second regions are halo regions.

7. The device of claim 3, wherein the second region is closer to the center line of the gate electrode than the first region by a distance about equal to a difference between the first and second thicknesses of the first and second spacers.

8. The device of claim 1, wherein the first thickness is about 1 nm to about 10 nm greater than the second thickness.

9. The device of claim 1, wherein the first thickness is at least about 10 nm greater than the second thickness.

10. The device of claim 1, wherein the first thickness is about 10 nm to about 100 nm greater than the second thickness.

11. A semiconductor device, comprising:
a structure;
a first doped region on a first side of a center of the structure;
a second doped region on a second side of the center of the structure, the second side being laterally opposite to the first side, the second doped region being the same type of doped region as the first doped region; and
wherein the second doped region is closer to the center of the structure than the first doped region.

12. The device of claim 11, wherein the structure is a gate electrode.

13. The device of claim 11, wherein the first and second doped regions are selected from the group consisting of halo regions, tip junction regions, and source/drain regions.

14. The device of claim 11, wherein the structure has a first sidewall and a second sidewall, the second sidewall being laterally opposite from the first sidewall, and further comprising:
a first spacer adjacent the first sidewall and having a first thickness; and
a second spacer adjacent the second sidewall of the gate electrode, the second spacer having a second thickness less than the first thickness.

15. The device of claim 14, wherein the second doped region is closer to the center of the structure than the first doped region by a distance about equal to a difference between the first and second thicknesses of the first and second spacers.

16. The device of claim 15 wherein the first thickness is at least about 10 nm greater than the second thickness.

17. A method to make a device, comprising:
forming a first spacer adjacent a first sidewall of a structure and a second spacer adjacent a second sidewall of the structure, the second sidewall being laterally opposite from the first sidewall; and
removing at least a portion of the first spacer so the first spacer is thinner than the second spacer.

18. The method of claim 17 wherein removing at least a portion of the first spacer comprises:
modifying the microstructure of at least a portion of the first spacer with an angled ion implant; and
removing, after modifying at least a portion of the first spacer, at least a portion of the first spacer with an etchant selective to the modified portion of the first spacer over the material of the second spacer.

19. The method of claim 18 wherein the angled ion implant is performed at an angle of at least forty-five degrees from vertical and the structure shields at least a substantial portion of the second spacer from the angled ion implant.

20. The method of claim 19 wherein the structure is a gate electrode on a substrate, further comprising doping the substrate to form a first doped region on a first side of the structure and a second doped region on a second side of the structure, the first and second doped regions being doped by the same doping operation, the first doped region being closer to a center of the gate electrode than the second doped region.
